(19) United States
(12) Patent Application Publication
(10) Pub. No.: US 2020/0203179 A1
(43) Pub. Date: Jun. 25, 2020

(54) METHOD FOR FABRICATING SEMICONDUCTOR COMPONENT

(71) Applicant: XIA TAI XIN SEMICONDUCTOR (QING DAO) LTD., Qingdao (CN)

(72) Inventors: KEEWOUNG CHOI, Singapore (SG); HASUNG LEE, Singapore (SG); SUNG-KI KIM, Singapore (SG)

(21) Appl. No.: 16/721,738

(22) Filed: Dec. 19, 2019

Related U.S. Application Data
(60) Provisional application No. 62/782,392, filed on Dec. 20, 2018.

(51) Int. Cl. H01L 21/3205; H01L 21/321; H01L 21/3215; H01L 21/324

(52) U.S. Cl. CPC H01L 21/32055; H01L 21/324; H01L 21/32155; H01L 21/3212

(57) ABSTRACT

A method for manufacturing a semiconductor component includes the following steps: performing polysilicon deposition on a surface of a semiconductor substrate to form a deposited layer; performing a chemical mechanical polishing on the deposited layer; performing a hydrogen implantation treatment or a hydrogen plasma treatment on the deposited layer; and performing an annealing process on the deposited layer at an annealing temperature of 600 degrees Celsius to 900 degrees Celsius to form a polysilicon contact layer.

### CROSS-REFERENCE TO RELATED APPLICATION(S)

This application claims to the benefit of U.S. Provisional Patent Application No. 62/782392 filed on Dec. 20, 2018, the contents of which are incorporated by reference herein.

### FIELD

The subject matter herein generally relates to a semiconductor, and more particularly to a method for fabricating the semiconductor component.

### BACKGROUND

Semiconductor memory device is configured to store data or program commands. Common memory devices include dynamic random access memory (DRAM), which is widely used in digital electronics. As the dimensions of semiconductor devices being reduced in response to increased demands for highly integrated semiconductor memory devices, which in turn causes the polysilicon contact layer in the semiconductor memory devices to decrease. During the manufacturing processes of the polysilicon contact layer, due to the miniaturization of the volume of the polysilicon contact layer, pores/seams can be easily formed during the chemical mechanical polishing or the etch back process, resulting in defective products or shortened product life.

### BRIEF DESCRIPTION OF THE DRAWINGS

Implementations of the present disclosure will now be described, by way of embodiments, with reference to the attached figures.

FIG. 1 is a flowchart of a first embodiment of a method for fabricating a semiconductor component.

FIG. 2 is a cross-sectional view of an embodiment of a semiconductor substrate.

FIG. 3 is a cross-sectional view showing a deposited layer on the semiconductor substrate of FIG. 2.

FIG. 4 is a flowchart of a second embodiment of a method for fabricating a semiconductor component.

FIG. 5 is a flowchart of a third embodiment of a method for fabricating a semiconductor component.

FIG. 6 is a flowchart of a fourth embodiment of a method for fabricating a semiconductor component.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

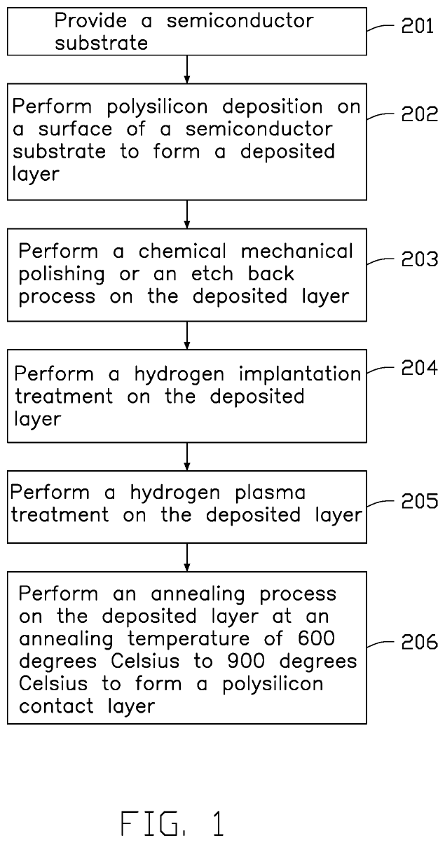

FIG. 1 illustrates a flowchart of a method in accordance with a first embodiment. The method for fabricating a semiconductor component is provided by way of embodiments, as there are a variety of ways to carry out the method. Each block shown in FIG. 1 represents one or more processes, methods, or subroutines carried out in the method. Furthermore, the illustrated order of blocks can be changed. Additional blocks may be added or fewer blocks may be utilized, without departing from this disclosure. The method can begin at block 201.

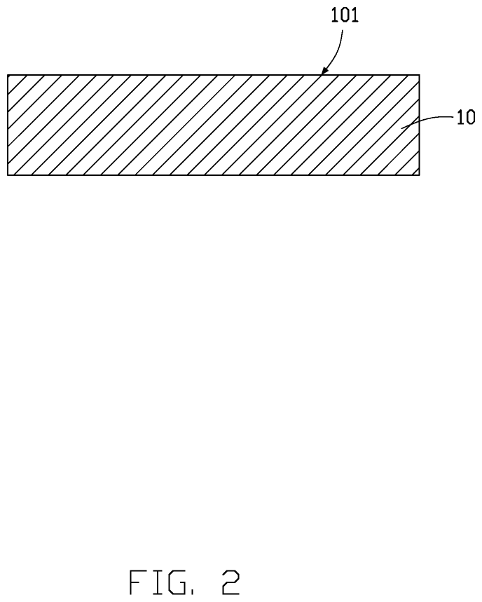

At block 201, referring to FIG. 2, a semiconductor substrate 10 is provided.

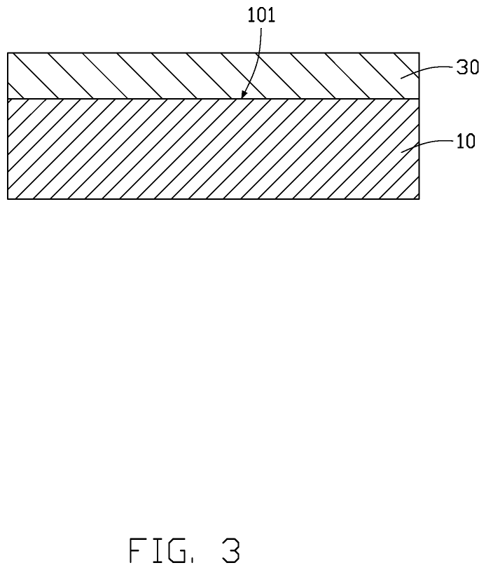

At block 202, referring to FIG. 3, a deposited layer 30 is formed on a surface 101 of the semiconductor substrate 10 by performing polysilicon deposition.

In at least one embodiment, the deposited layer 30 is formed by Chemical Vapor Deposition. More specifically, the deposited layer 30 is formed by Low Pressure Chemical Vapor Deposition. The Low Pressure Chemical Vapor Deposition is performed at a temperature in a range of 575 degrees Celsius to 650 degrees Celsius.

In at least one embodiment, SiH₄ is pumped into a chamber for Low Pressure Chemical Vapor Deposition. SiH₄ is poyrolized to obtain Si at the temperature in a range of 575 degrees Celsius to 650 degrees Celsius. Si is deposited on the surface 101 of the semiconductor substrate 10 to obtain polysilicon, thereby obtaining the deposited layer 30. A pressure of the Low Pressure Chemical Vapor Deposition is in a range of 10 mTorr to 350 mTorr, and a deposition rate of the Low Pressure Chemical Vapor Deposition is in a range of 15 Å/min to 300 Å/min.

A thickness of the deposited layer 30 may be varied as needed.

At block 203, a chemical mechanical polishing or an etch back process is performed on the deposited layer 30.

At block 204, a hydrogen implantation treatment is performed on the deposited layer 30 after performing the chemical mechanical polishing or the etch back process.

In at least one embodiment, an implantation amount of hydrogen atoms in the hydrogen implantation treatment is 10¹³/cm² or more, and an acceleration energy of hydrogen atoms in the hydrogen implantation treatment is 3 MeV or less.

At block 205, a hydrogen plasma treatment is performed on the deposited layer 30 after performing the hydrogen implantation treatment.

In at least one embodiment, a flow rate of the hydrogen plasma treatment is in a range of 1000 sccm to 2000 sccm, a pressure of the hydrogen plasma treatment is in a range of 10 mTorr to 100 mTorr. In at least one embodiment, the hydrogen plasma treatment is performed for 2 minutes to 4.5 minutes.

At block 206, an annealing process is performed on the deposited layer after performing the hydrogen plasma treatment at an annealing temperature of 600 degrees Celsius to 900 degrees Celsius to form a polysilicon contact layer.

In at least one embodiment, the annealing process is performed on the deposited layer 30 for 30 minutes or more.

In at least one embodiment, the annealing process may be performed in a vacuum environment. In another embodiment, the annealing process may be performed in a hydrogen gas environment.

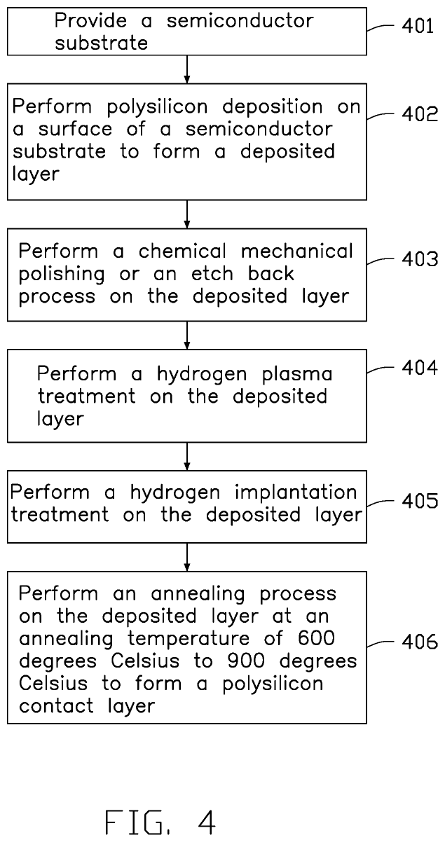

FIG. 4 illustrates a flowchart of a second embodiment of a method for fabricating a semiconductor component. The method can begin at block 401.

At block 401, referring to FIG. 2, a semiconductor substrate 10 is provided.

At block 402, referring to FIG. 3, a deposited layer 30 is formed on a surface 101 of the semiconductor substrate 10 by performing polysilicon deposition.

In at least one embodiment, the deposited layer 30 is formed by Chemical Vapor Deposition. More specifically, the deposited layer 30 is formed by Low Pressure Chemical Vapor Deposition. The Low Pressure Chemical Vapor Deposition is performed at a temperature in a range of 575 degrees Celsius to 650 degrees Celsius.

In at least one embodiment, SiH₄ is pumped into a chamber for Low Pressure Chemical Vapor Deposition. SiH₄ is poyrolized to obtain Si at the temperature in a range of 575 degrees Celsius to 650 degrees Celsius. Si is deposited on the surface 101 of the semiconductor substrate 10 to obtain polysilicon, thereby obtaining the deposited layer 30. A pressure of the Low Pressure Chemical Vapor Deposition is in a range of 10 mTorr to 350 mTorr, and a deposition rate of the Low Pressure Chemical Vapor Deposition is in a range of 15 Å/min to 300 Å/min.

A thickness of the deposited layer 30 may be varied as needed.

At block 403, a chemical mechanical polishing or an etch back process is performed on the deposited layer 30.

At block 404, a hydrogen plasma treatment is performed on the deposited layer 30 after performing the chemical mechanical polishing or the etch back process.

In at least one embodiment, a flow rate of the hydrogen plasma treatment is in a range of 1000 sccm to 2000 sccm, a pressure of the hydrogen plasma treatment is in a range of 10 mTorr to 100 mTorr. In at least one embodiment, the hydrogen plasma treatment is performed for 2 minutes to 4.5 minutes.

At block 405, a hydrogen implantation treatment is performed on the deposited layer 30 after performing the hydrogen plasma treatment.

In at least one embodiment, an implantation amount of hydrogen atoms in the hydrogen implantation treatment is 10¹³/cm² or more, and an acceleration energy of hydrogen atoms in the hydrogen implantation treatment is 3 MeV or less.

At block 406, an annealing process is performed on the deposited layer after performing the hydrogen implantation treatment at an annealing temperature of 600 degrees Celsius to 900 degrees Celsius to form a polysilicon contact layer.

In at least one embodiment, the annealing process is performed on the deposited layer 30 for 30 minutes or more.

In at least one embodiment, the annealing process may be performed in a vacuum environment. In another embodiment, the annealing process may be performed in a hydrogen gas environment.

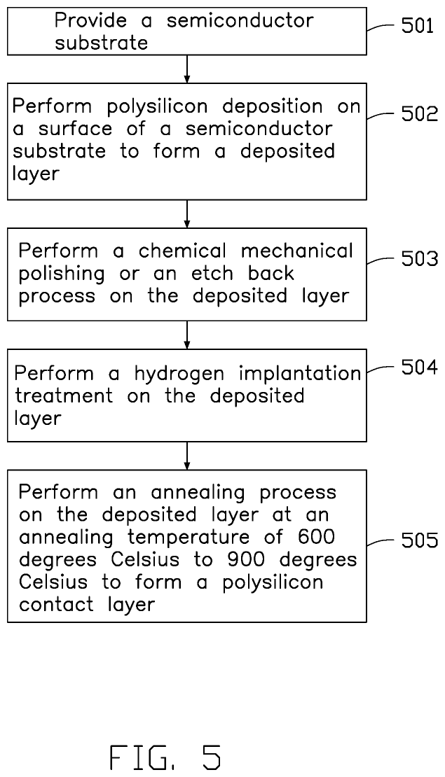

FIG. 5 illustrates a flowchart of a third embodiment of a method for fabricating a semiconductor component. The method can begin at block 501.

At block 501, referring to FIG. 2, a semiconductor substrate 10 is provided.

At block 502, referring to FIG. 3, a deposited layer 30 is formed on a surface 101 of the semiconductor substrate 10 by performing polysilicon deposition.

In at least one embodiment, the deposited layer 30 is formed by Chemical Vapor Deposition. More specifically, the deposited layer 30 is formed by Low Pressure Chemical Vapor Deposition. The Low Pressure Chemical Vapor Deposition is performed at a temperature in a range of 575 degrees Celsius to 650 degrees Celsius.

In at least one embodiment, SiH₄ is pumped into a chamber for Low Pressure Chemical Vapor Deposition. SiH₄ is poyrolized to obtain Si at the temperature in a range of 575 degrees Celsius to 650 degrees Celsius. Si is deposited on the surface 101 of the semiconductor substrate 10 to obtain polysilicon, thereby obtaining the deposited layer 30. A pressure of the Low Pressure Chemical Vapor Deposition is in a range of 10 mTorr to 350 mTorr, and a deposition rate of the Low Pressure Chemical Vapor Deposition is in a range of 15 Å/min to 300 Å/min.

A thickness of the deposited layer 30 may be varied as needed.

At block 503, a chemical mechanical polishing or an etch back process is performed on the deposited layer 30.

At block 504, a hydrogen implantation treatment is performed on the deposited layer 30 after performing the chemical mechanical polishing or the etch back process.

In at least one embodiment, an implantation amount of hydrogen atoms in the hydrogen implantation treatment is 10¹³/cm² or more, and an acceleration energy of hydrogen atoms in the hydrogen implantation treatment is 3 MeV or less.

At block 505, an annealing process is performed on the deposited layer after performing the hydrogen implantation treatment at an annealing temperature of 600 degrees Celsius to 900 degrees Celsius to form a polysilicon contact layer.

In at least one embodiment, the annealing process is performed on the deposited layer 30 for 30 minutes or more.

In at least one embodiment, the annealing process may be performed in a vacuum environment. In another embodiment, the annealing process may be performed in a hydrogen gas environment.

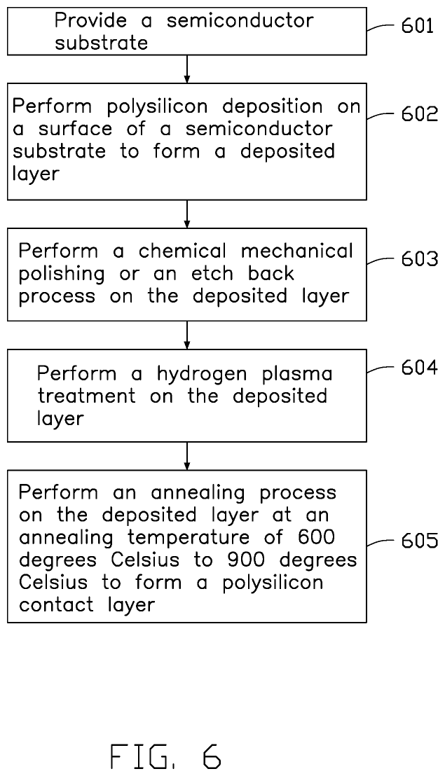

FIG. 6 illustrates a flowchart of a second embodiment of a method for fabricating a semiconductor component. The method can begin at block 601.

At block 601, referring to FIG. 2, a semiconductor substrate 10 is provided.

At block 602, referring to FIG. 3, a deposited layer 30 is formed on a surface 101 of the semiconductor substrate 10 by performing polysilicon deposition.

In at least one embodiment, the deposited layer 30 is formed by Chemical Vapor Deposition. More specifically, the deposited layer 30 is formed by Low Pressure Chemical Vapor Deposition. The Low Pressure Chemical Vapor Deposition is performed at a temperature in a range of 575 degrees Celsius to 650 degrees Celsius.

In at least one embodiment, SiH₄ is pumped into a chamber for Low Pressure Chemical Vapor Deposition. SiH₄ is poyrolized to obtain Si at the temperature in a range of 575 degrees Celsius to 650 degrees Celsius. Si is deposited on the surface 101 of the semiconductor substrate 10 to obtain polysilicon, thereby obtaining the deposited layer 30. A pressure of the Low Pressure Chemical Vapor Deposition is in a range of 10 mTorr to 350 mTorr, and a deposition rate of the Low Pressure Chemical Vapor Deposition is in a range of 15 Å/min to 300 Å/min.

A thickness of the deposited layer 30 may be varied as needed.

At block 603, a chemical mechanical polishing or an etch back process is performed on the deposited layer 30.

At block 604, a hydrogen plasma treatment is performed on the deposited layer 30 after performing the chemical mechanical polishing or the etch back process.

In at least one embodiment, a flow rate of the hydrogen plasma treatment is in a range of 1000 sccm to 2000 sccm, a pressure of the hydrogen plasma treatment is in a range of 10 mTorr to 100 mTorr. In at least one embodiment, the hydrogen plasma treatment is performed for 2 minutes to 4.5 minutes.

At block 605, an annealing process is performed on the deposited layer after performing the hydrogen plasma treatment at an annealing temperature of 600 degrees Celsius to 900 degrees Celsius to form a polysilicon contact layer.

In at least one embodiment, the annealing process is performed on the deposited layer 30 for 30 minutes or more.

In at least one embodiment, the annealing process may be performed in a vacuum environment. In another embodiment, the annealing process may be performed in a hydrogen gas environment.

The method for fabricating the semiconductor component has a simple process and is easy to operate. In the above methods, before annealing, the hydrogen implantation treatment or the hydrogen plasma treatment is performed on the deposited layer to eliminate dangling bonds of the deposited layer, thereby helping to reduce the temperature required for annealing and avoiding damage to the semiconductor component caused by the annealing temperature higher than 1000° C. in the prior art. In addition, by the hydrogen implantation treatment or the hydrogen plasma treatment in combination with the above annealing treatment, seams in the polysilicon contact layer can be eliminated, thereby improving product yield and service life.

Depending on the embodiments, certain steps of the methods described may be removed, others may be added, and the sequence of steps may be altered. It is also to be understood that the description and the claims drawn to a method may include some indication in reference to sequential steps. However, the indication used is only to be viewed for identification purposes and not as a suggestion as to an order for the steps.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A method for manufacturing a semiconductor component comprising:
performing polysilicon deposition on a surface of a semiconductor substrate to form a deposited layer;
performing a chemical mechanical polishing on the deposited layer;
performing a hydrogen implantation treatment or a hydrogen plasma treatment on the deposited layer; and
performing an annealing process on the deposited layer at an annealing temperature in a range of 600 degrees Celsius to 900 degrees Celsius to form a polysilicon contact layer.

2. The method of claim 1, wherein the annealing process is performed on the deposited layer for 30 minutes or more.

3. The method of claim 1, wherein performing the hydrogen implantation treatment or the hydrogen plasma treatment on the deposited layer comprises:
performing the hydrogen implantation treatment on the deposited layer after performing the chemical mechanical polishing; and
performing the hydrogen plasma treatment on the deposited layer after performing the hydrogen implantation treatment.

4. The method of claim 1, wherein performing the hydrogen implantation treatment or the hydrogen plasma treatment on the deposited layer comprises:
performing the hydrogen plasma treatment on the deposited layer after performing the chemical mechanical polishing; and
performing the hydrogen implantation treatment on the deposited layer after performing the hydrogen plasma treatment.

5. The method of claim 1, wherein the annealing process is performed in a vacuum environment.

6. The method of claim 1, wherein the annealing process is performed in a hydrogen gas environment.

7. The method of claim 1, wherein a flow rate of the hydrogen plasma treatment is in a range of 1000 sccm to 2000 sccm, a pressure of the hydrogen plasma treatment is in a range of 10 mTorr to 100 mTorr; and/or an implantation amount of hydrogen atoms in the hydrogen implantation treatment is 10¹³/cm² or more, and an acceleration energy of hydrogen atoms in the hydrogen implantation treatment is 3 MeV or less.

8. The method of claim 1, wherein when the method comprises the hydrogen plasma treatment, the hydrogen plasma treatment is performed for 2 minutes to 4.5 minutes.

9. The method of claim 1, wherein the deposited layer is formed by a Low Pressure Chemical Vapor Deposition.

10. The method of claim 9, wherein the Low Pressure Chemical Vapor Deposition is performed at a temperature in a range of 575 degrees Celsius to 650 degrees Celsius.

11. A method for manufacturing a semiconductor component comprising:
performing polysilicon deposition on a surface of a semiconductor substrate to form a deposited layer;
performing an etch back process on the deposited layer;
performing a hydrogen implantation treatment or a hydrogen plasma treatment on the deposited layer; and performing an annealing process on the deposited layer at an annealing temperature of 600 degrees Celsius to 900 degrees Celsius to form a polysilicon contact layer.

12. The method of claim 11, wherein the annealing process is performed on the deposited layer for 30 minutes or more.

13. The method of claim 11, wherein performing the hydrogen implantation treatment or the hydrogen plasma treatment on the deposited layer comprises:
performing the hydrogen implantation treatment on the deposited layer after performing the etch back process; and
performing the hydrogen plasma treatment on the deposited layer after performing the hydrogen implantation treatment.

14. The method of claim 11, wherein performing the hydrogen implantation treatment or the hydrogen plasma treatment on the deposited layer comprises:
performing the hydrogen plasma treatment on the deposited layer after performing the etch back process; and
performing the hydrogen implantation treatment on the deposited layer after performing the hydrogen plasma treatment.

15. The method of claim 11, wherein the annealing process is performed in a vacuum environment.

16. The method of claim 11, wherein the annealing process is performed in a hydrogen gas environment.

17. The method of claim 11, wherein a flow rate of the hydrogen plasma treatment is in a range of 1000 sccm to 2000 sccm, a pressure of the hydrogen plasma treatment is in a range of 10 mTorr to 100 mTorr; and/or an implantation amount of hydrogen atoms in the hydrogen implantation treatment is 10¹³/cm² or more, and an acceleration energy of hydrogen atoms in the hydrogen implantation treatment is 3 MeV or less.

18. The method of claim 11, wherein when the method comprises the hydrogen plasma treatment, the hydrogen plasma treatment is performed for 2 minutes to 4.5 minutes.

19. The method of claim 1, wherein the deposited layer is formed by a Low Pressure Chemical Vapor Deposition.

20. The method of claim 19, wherein the Low Pressure Chemical Vapor Deposition is performed at a temperature in a range of 575 degrees Celsius to 650 degrees Celsius.
